(19) United States
(12) Patent Application Publication
(10) Pub. No.: US 2015/0128617 A1
(43) Pub. Date: May 14, 2015

(54) Closed Cryogen Cooling System And Method For Cooling A Superconducting Magnet

(71) Applicant: SIEMENS PLC, Camberley (GB)

(72) Inventor: Vladimir Mikheev, Oxfordshire (GB)

(73) Assignee: SIEMENS PLC, Camberley (GB)

(21) Appl. No.: 14/401,251

(22) PCT Filed: Apr. 24, 2013
(86) PCT No.: PCT/EP2013/058556

§ 371 Date: Nov. 14, 2014

(30) Foreign Application Priority Data
Jun. 1, 2012 (GB) 1209853.9

(51) Int. Cl. G01R 33/38; F17C 13/02; F17C 5/00

(52) U.S. Cl. CPC G01R 33/3804; F17C 5/00; F17C 13/021
USPC 62/47.1

(57) ABSTRACT

In a cryogen cooling system for cooling a superconducting magnet, a cryogen vessel is linked to a cooling loop arrangement in thermal contact with the superconducting magnet. A recondensing chamber is arranged such that a lower extremity of the cryogen vessel is above a lower extremity of the recondensing chamber. A recondensing refrigerator is arranged to recondense cryogen gas within the recondensing chamber. A heater is positioned to heat gaseous cryogen within the recondensing chamber, and wherein the recondensing chamber is hydraulically connected to the cryogen vessel by a cryogen supply pipe. An upper end of the cryogen supply pipe is exposed to cryogen gas in the cryogen vessel and a lower end of cryogen supply pipe is exposed to an interior of the recondensing chamber towards or at its lower extremity.

### BACKGROUND

Early superconducting magnets for MRI systems were cooled by partial immersion in a bath of liquid cryogen. However, more recent designs have reduced the quantity of liquid cryogen required, typically by using a cooling loop arrangement. Such systems usually have a relatively small cryogen vessel positioned at the top of the cooling loop and below a recondensing refrigerator, to provide liquid cryogen which is fed into thermal contact with the magnet under the influence of gravity. Warmed, or boiled, cryogen returns through the cooling loop to the cryogen vessel for recooling. However, such an arrangement tends to have a height greater than the available height within a typical installation room. The positioning of the recondensing refrigerator at the top of the magnet is inconvenient for servicing and replacement of the recondensing refrigerator.

Some conventional arrangements provide a recondensing refrigerator at a reduced height, thermally linked to a cryogen vessel through a solid thermal bus-bar. However, at the temperature required to re-condense cryogens such as helium, a cooling power of only 1 W is common. The solid bus-bar may need to have a length of about 1 m and needs to be highly thermally conductive. Such bus-bars are typically made from high purity annealed copper or high purity annealed aluminum with a very large cross-sectional area in order to transfer cooling power from the refrigerator to the cryogen vessel without significant loss. They are very expensive to produce. For example, a conventional 50 cm bus bar may cause a temperature rise of 0.1 K or more. This makes the bus bar arrangement bulky and expensive to manufacture. It has been found difficult to produce perfectly flat contact surfaces for the thermal connection between the bus bar and the refrigerator. This tends to result in only point contacts which can be improved by filling the joint with indium or grease, or mechanically compressing the joints. However, such joints are difficult to make. Replacement of the recondensing refrigerator in the field may mean that the contacts need to be reproduced on site, which is found to be unreliable. Imperfect connections result in lost cooling power and may result in loss of cryogen.

The present disclosure relates to cooling arrangements for cryogen cooled superconducting magnets such as used in MRI systems. In particular it relates to arrangements for controlling the level of liquid cryogen in a cryogen vessel of compact magnet systems.

Background information on conventional arrangements is provided in US patents U.S. Pat. No. 4,464,904; U.S. Pat. No. 5,335,503; U.S. Pat. No. 5,549,142; U.S. Pat. No. 5,937,655; U.S. Pat. No. 6,996,994 and Japanese patent publication JP2004033260.

### SUMMARY

It is an object to provide an arrangement in which a cryogen vessel is arranged no higher than the top of a cryostat housing a superconducting magnet, yet which allows cryogen gas to be re-condensed and supplied to the cryogen vessel near the top of the superconducting magnet to be fed to a cooling loop.

Conventional MRI cooling systems have a recondensing refrigerator arranged to liquefy cryogen gas within a cryogen vessel. The liquefied cryogen gas is then fed to a cooling loop under the influence of gravity. In the present preferred embodiment, the recondensing refrigerator is not placed above the magnet, but is provided in association with a separate recondensing chamber, positioned rather lower than the cryogen vessel connected to the cooling loop.

Such arrangements are particularly useful where MRI systems are to be installed in locations where available height is limited.

In a cryogen cooling system for cooling a superconducting magnet, a cryogen vessel is linked to a cooling loop arrangement in thermal contact with the superconducting magnet. A recondensing chamber is arranged such that a lower extremity of the cryogen vessel is above a lower extremity of the recondensing chamber. A recondensing refrigerator is arranged to recondense cryogen gas within the recondensing chamber. A heater is positioned to heat gaseous cryogen within the recondensing chamber, and wherein the recondensing chamber is hydraulically connected to the cryogen vessel by a cryogen supply pipe. An upper end of the cryogen supply pipe is exposed to cryogen gas in the cryogen vessel and a lower end of cryogen supply pipe is exposed to an interior of the recondensing chamber towards or at its lower extremity.

The above and further objects characteristics and advantages of the present preferred embodiments will become more apparent from consideration of the following description of certain embodiments given by way of example only, in conjunction with the following accompanying drawings.

### BRIEF DESCRIPTION OF THE DRAWINGS

FIGS. 1 to 4 schematically illustrate example cooling arrangements of the present exemplary embodiments.

### DESCRIPTION OF EXEMPLARY EMBODIMENTS

For the purposes of promoting an understanding of the principles of the invention, reference will now be made to preferred exemplary embodiments/best mode illustrated in the drawings and specific language will be used to describe the same. It will nevertheless be understood that no limitation of the scope of the invention is thereby intended, and such alterations and further modifications in the illustrated embodiments and such further applications of the principles of the invention as illustrated as would normally occur to one skilled in the art to which the invention relates are included herein.

The present preferred embodiment provides a cryogen cooling system comprising two hydraulically connected reservoirs. The system operates a closed cryogenic cycle, including liquefaction and evaporation.

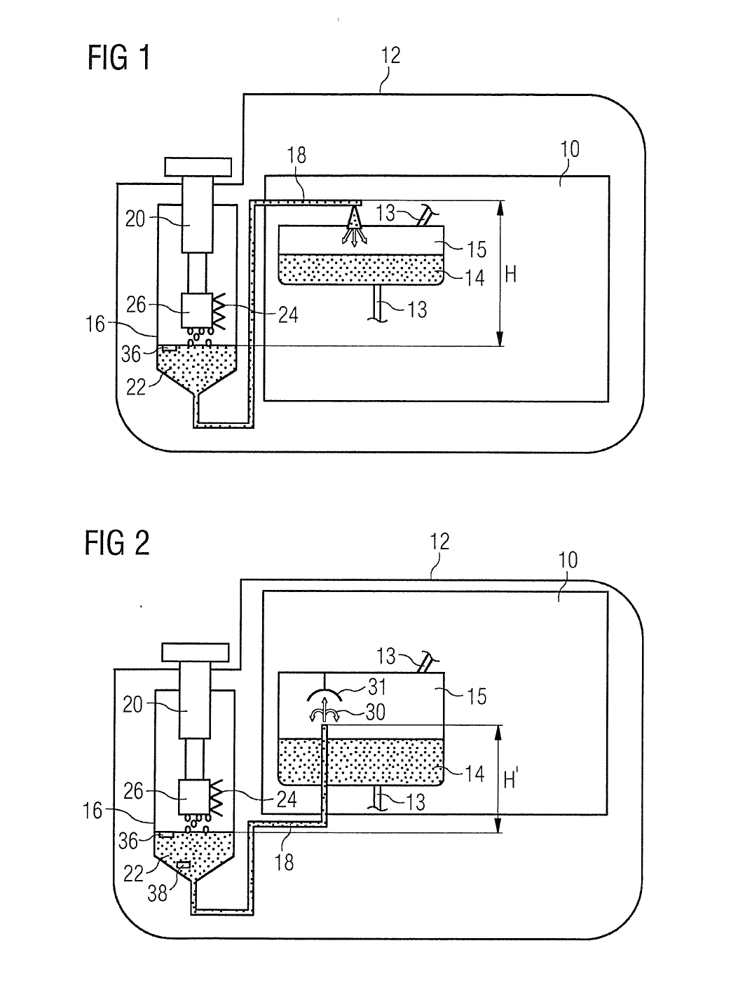

In FIG. 1, a superconducting magnet 10 is housed within an evacuated cryostat 12 and is provided with a cooling loop arrangement 13 which is supplied with by liquid cryogen 14 from a cryogen vessel 15 positioned near the top of the magnet 10. The cryogen may be helium, although other suitable cryogens are known to those skilled in the art. Liquid cryogen 22 is provided from a recondensing chamber 16 through cryogen supply pipe 18 connected at one end near a lower extremity of recondensing chamber 16 and connected at the other end near an upper extremity of cryogen vessel 15. A recondensing refrigerator 20 is arranged to recondense cryogen vapour within the recondensing chamber 16 into liquid cryogen 22, at a temperature of about 4.2 K in the case of helium. According to an aspect of the invention, a lower extremity of the cryogen vessel 15 is above the lower extremity of recondensing chamber 16. As illustrated, liquid cryogen from recondensing chamber 16 must rise a height H to reach cryogen vessel 15. Height H may typically be between 0.5 to 1.0 m. A heater 24 is positioned within, or at least in thermal contact with, the recondensing chamber 16. In FIG. 1, this heater is shown attached to the recondensing surface 26 of the recondensing refrigerator 20, but may be positioned elsewhere within thermal contact with the recondensing chamber 16. It may be integrated into the recondensing refrigerator 20. It may be placed on an exterior surface of the recondensing chamber 16. The recondensing vessel is thermally insulated by vacuum space from the cryogen vessel 15.

According to an aspect of the exemplary embodiment, liquid helium from recondensing chamber 16 is driven up through pipe 18 to the cryogen vessel 15 by controlled variation in the pressure of cryogen gas within recondensing chamber 16.

An example method of operation of the present exemplary embodiment may proceed as follows. In a steady state, recondensing refrigerator 20 operates at a working temperature of 4.2 K in contact with helium gas at a pressure of 14.5 psi (100 kPa) absolute within the recondensing chamber 16. The recondensing refrigerator may have an effective cooling power of 1 W at 4.2 K. Helium gas within the cryogen vessel 15 is a standard pressure of 15.3 psi (105.5 kPa) absolute. This pressure, being higher than the gas pressure within the recondensing chamber 16, drives helium gas from cryogen vessel 15 into recondensing chamber 16. In the recondensing chamber 16, the helium gas is liquefied and maintains a gas pressure lower than that in the cryogen vessel 15. Accordingly, cryogen gas tends to flow from cryogen vessel 15 to recondensing chamber 16. Once a predetermined quantity of liquid helium has accumulated within the recondensing chamber 16, operation of the recondensing refrigerator 20 may cease, heater 24 is then energised and warms cryogen gas within the recondensing chamber 16. The recondensation stops and the pressure of cryogen gas within the recondensing chamber 16 rises. Once the pressure of cryogen gas within the recondensing chamber 16 rises above the pressure of cryogen gas in cryogen vessel 15 by a sufficient amount, liquid cryogen 22 is forced from the recondensing chamber 16 through pipe 18 into the cryogen vessel 15. Once the level of liquid cryogen within the recondensing chamber 16 reaches a predetermined minimum level, which may be “empty”, the heater 24 is de-energised and re-condensation of helium gas will recommence. This operation will continue cyclically to ensure that a supply of liquid cryogen is always provided within cryogen vessel 15, by periodically replenishing the cryogen vessel 15 with liquid cryogen from the re-condensing chamber 16.

In this example, the present exemplary embodiment makes use of the relatively low density of liquid helium and the relatively large coefficient of thermal expansion of gaseous helium. Atmospheric pressure corresponds to approximately 10 m height of water or 80 m height of liquid helium. This means that a relatively low pressure difference is required. Only about 10 mbar or 1% of atmospheric pressure should be sufficient to raise liquid helium over 800 mm.

There is only a very small temperature difference between liquid cryogen in the recondensing chamber 16 and liquid cryogen in the cryogen vessel 15, and the thermal conductivity of liquid helium is relatively low, so any heat load on the recondensing vessel due to the pipe 18 is likely to be insignificant.

The upper end of pipe 18 is exposed to cryogen gas in the cryogen vessel 15. The lower end of pipe 18 is exposed to the interior of recondensing chamber 16 towards or at its lower extremity. Once a small quantity of liquid cryogen is recondensed in the recondensing chamber 16, the lower end of pipe 18 will be immersed in liquid cryogen forming a hydraulic lock. The pressure difference in gaseous cryogen between the cryogen vessel 15 and the recondensing chamber 16 will be sufficient to draw gaseous cryogen from cryogen vessel 15 through pipe 18 to recondensing chamber 16 when recondensing refrigerator 20 is in operation. Recondensation of gaseous cryogen in the recondensing chamber 16 will keep the gas pressure within the recondensing chamber 16 lower than gas pressure in cryogen vessel 15.

If the gas pressure within the recondensing chamber 16 is sufficient, and the cooling power of the recondensing refrigerator 20 is known, one can calculate the rate at which cryogen will condense, and cycles of replenishing the cryogen vessel 15 may simply be timed. For instance, cooling helium at 4.2K at a power of 1 W will cause about 1 litre of liquid helium to recondense in one hour. At predetermined time intervals, corresponding to expected quantities of recondensed cryogen, operation of the recondensing refrigerator 20 may cease, and heater 24 may be energized. The resulting heating of gaseous cryogen will cause expansion of the gas and an increase of gas pressure within recondensing chamber 16. Once that gas pressure exceeds the gas pressure within the cryogen vessel 15 sufficiently, liquid cryogen 22 will be driven from recondensation chamber 16 into cryogen vessel 15. The heating may be continued for a fixed period of time, deemed sufficient to drive all, or a predicted quantity, of the liquid cryogen from recondensation chamber 16 to cryogen vessel 15. Alternatively, sensors may be provided to detect a minimum level of liquid cryogen 22 in the recondensing chamber 16, or a maximum level of liquid cryogen in the cryogen vessel 15, and the heater 24 may be de-energized as soon as one of these sensors indicates that one of these conditions has been reached. Similarly, a sensor may be provided to detect a maximum level of liquid cryogen within the recondensing chamber 16, or a minimum level of liquid cryogen within the cryogen vessel 15 and to energise heater 24 once this maximum level is reached.

In the case of helium cryogen, the expansion coefficient at about 4K is so large that only a very small temperature rise, in the order of 10 mK, is expected to be sufficient to create a pressure increase of about 10 mbar and drive liquid helium up a height H of about 800 mm.

If heater 24 remains energized for long enough, all of the liquid cryogen within recondensing chamber 16 will be driven into the cryogen vessel 15. At this point the gas pressures within recondensing chamber 16 and cryogen vessel 15 will equalize. Heater 24 is then de-energized and the sequence repeats.

In alternative arrangements, the refrigerator 20 may remain operational while heater 24 is energized, the cooling power of the refrigerator 20 being easily overcome by the heating effect of a simple electrical heater 24.

The heater may be a simple coil of resistive wire provided with an electrical current by electrical connections integrated into the refrigerator 20. The heater itself may be integrated into the recondensing refrigerator, for example being attached to an outer surface. Alternatively, the heater may be placed on the outer surface of recondensing chamber 16, in thermal contact with it.

The depth of liquid helium within recondensing chamber 16 may be monitored by temperature sensors placed at appropriate locations either within or on the external surface of the recondensing chamber 16. The temperature sensors may be electrical resistors, or any other known level gauges such as those relying upon capacitance, superconduction etc., suitably connected to a control system. The control system may use measurements provided by the sensors to control the operation of the heater 24 and a drive the hydraulic lift of liquid cryogen from recondensing chamber 16 into cryogen vessel 15.

The recondensing chamber 16 need not be located immediately adjacent to the cryogen vessel 15 but may be positioned elsewhere in a room with the MRI system. However, suitable thermal insulation must be provided around the pipe 18 connecting the recondensing chamber 16 with the cryogen vessel 15. Such thermal insulation will typically include vacuum insulation.

FIG. 2 shows an alternative exemplary embodiment. In this embodiment, the pipe 18 enters the cryogen vessel 15 near its lower extremity, and continues upward inside the cryogen vessel 15 to a maximum height H′ above a maximum liquid cryogen level in the recondensing chamber 16, which may be significantly less than the corresponding height H of the embodiment of FIG. 1. In this arrangement, liquid cryogen may be raised from recondensing chamber 16 to cryogen vessel 15 by a much smaller differential gas pressure than in the case of the embodiment of FIG. 1. Although not necessary, the illustrated embodiment shows an upwardly-directed upper end of pipe 18, wherefrom liquid cryogen may emerge as a fountain 30. An umbrella 31 may be provided above the upper end of pipe 18. The purpose of such an umbrella is as follows. If the cryogen vessel 15 contains a relatively low level of liquid cryogen, then its upper surface may be relatively warm. The umbrella prevents direct contact between the incoming liquid cryogen, to ensure that the liquid helium is not warmed by the upper surface of the cryogen vessel, leaving the upper surface of the cryogen vessel to be cooled by circulation of the warmer cryogen gas within the cryogen vessel.

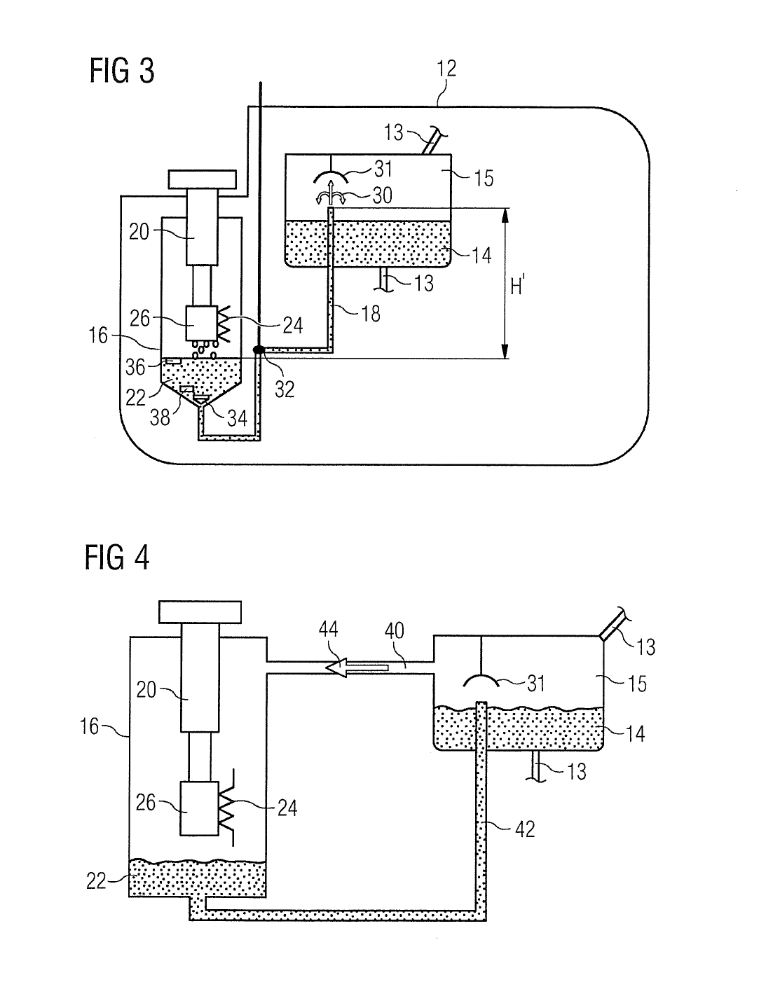

FIG. 3 shows a development of the embodiment of FIG. 2. Here, a valve 32 is provided, to control the flow of liquid cryogen 22 from the recondensing chamber 16 to the cryogen vessel 15, and the flow of cryogen gas from the cryogen vessel 15 to the recondensation chamber 16. The valve 32 may be controlled manually or automatically by a magnet control system or otherwise. If a service operation is required, which necessitates removal of the refrigerator 20, valve 32 should be closed before the refrigerator is removed, to prevent ingress of air into the cryogen vessel 15.

Also shown is an optional further valve 34, which may be also or alternatively be used to prevent ingress of air into the cryogen vessel 15 during servicing operations within the recondensing chamber, such as replacement of recondensing refrigerator 20.

In FIGS. 1-3, a maximum liquid cryogen level sensor 36 is shown within the recondensing chamber 16. This sensor is used to detect the filling of the recondensing chamber 16 to a predetermined maximum level and output from this sensor may be provided to a controller and in response, the controller may activate heater 24 to begin driving liquid cryogen 22 from the recondensing chamber 16 into the cryogen vessel 15. Also shown in FIGS. 2 and 3 is a minimum liquid cryogen level sensor 38 within the recondensing chamber 26. This sensor is used to indicate that heater 24 should be de-energized to stop the flow of liquid cryogen 22 from recondensing chamber 16 to cryogen vessel 15. In the embodiment of FIG. 1, no minimum liquid cryogen level sensor is provided. Instead, heater 24 may simply be energised for a predetermined period of time sufficient to drive a predicted quantity of liquid cryogen 22 into the cryogen vessel 15. Alternatively, if required, the heater 24 may be energized for a time sufficient to drive all liquid cryogen from recondensing chamber 16 into cryogen vessel 15. Temperature sensors 36, 38 may alternatively be positioned on an outer surface of the recondensing chamber 16.

It is preferred that the open end of pipe 18 should be quite near the upper surface of the cryogen vessel, such that the warmer cryogen gas nearer the top of the cryogen vessel is taken for recondensation. This is believed to result in improved thermal stability of the cryogen vessel.

The total quantity of cryogen within the recondensing chamber 16 and cryogen vessel 15 is preferably determined such that the upper end of pipe 18 always remains above the liquid level in cryogen vessel 15.

The present exemplary embodiments accordingly provide apparatus and methods for replenishing a cryogen vessel arranged for cooling a superconducting magnet in which a recondensing refrigerator is provided at a height significantly below that of conventional arrangements the inventive arrangement is simple and compact. The cost of manufacture of the arrangement of the present exemplary embodiments are significantly less than that of conventional arrangements. The relative positioning of the recondensing chamber and the cryogen vessel is very flexible and allows easy replacement of the refrigerator when required. The use of the optional valve allows for the warming of the recondensing chamber to room temperature while maintaining cryogenic temperatures within the cryogen vessel.

FIG. 4 shows another alternative exemplary embodiment in which two pipes 40, 42 are provided, linking the recondensing chamber 16 and the cryogen vessel 15. A first pipe 40 links an upper part of the recondensing chamber 16 with an upper part of the cryogen vessel 15, and serves to carry cryogen gas from the cryogen vessel 15 to the recondensing chamber 16. A one-way valve 44 is provided within this tube, to prevent cryogen gas flow in the reverse direction when heater 24 is active. The second pipe 42 joins lower parts of the recondensing chamber 16 and the cryogen vessel 15, and provides a passage for the flow of liquid cryogen from the recondensing chamber to the cryogen vessel 15.

Although preferred exemplary embodiments are shown and described in detail in the drawings and in the preceding specification, they should be viewed as purely exemplary and not as limiting the invention. It is noted that only preferred exemplary embodiments are shown and described, and all variations and modifications that presently or in the future lie within the protective scope of the invention should be protected.

1-21. (canceled)

22. A cryogen cooling system for cooling a superconducting magnet, comprising:
a cryogen vessel linked to a cooling loop arrangement in thermal contact with the superconducting magnet;
a recondensing chamber arranged such that a lower extremity of the cryogen vessel is above a lower extremity of the recondensing chamber;
a recondensing refrigerator arranged to recondense cryogen gas within the recondensing chamber; and
a heater positioned to heat gaseous cryogen within the recondensing chamber, and wherein the recondensing chamber is hydraulically connected to the cryogen vessel by a cryogen supply pipe, an upper end of the cryogen supply pipe being exposed to cryogen gas in the cryogen vessel and a lower end of the cryogen supply pipe being exposed to an interior of the recondensing chamber towards or at its lower extremity.

23. The cryogen cooling system according to claim 22 further comprising a sensor for detecting a minimum level of the liquid cryogen in the recondensing chamber.

24. The cryogen cooling system according to claim 22 further comprising a sensor for detecting a maximum level of the liquid cryogen in the recondensing chamber.

25. The cryogen cooling system according to claim 22 further comprising a sensor for detecting a maximum level of the liquid cryogen in the cryogen vessel.

26. The cryogen cooling system according to claim 22 further comprising a controller arranged to energize and de-energize the heater in response to signals provided by the sensor, or one of the sensors.

27. The cryogen cooling system according to claim 22 further comprising a valve provided to control flow through the cryogen supply pipe.

28. The cryogen cooling system according to claim 22 further comprising a removable plug for closing the lower end of the cryogen supply pipe.

29. The cryogen cooling system according to claim 22 wherein the heater is integrated into the recondensing refrigerator.

30. The cryogen cooling system according to claim 22 wherein the heater is attached to an outer surface of the recondensing chamber in thermal contact with the recondensing chamber.

31. The cryogen cooling system according to claim 22 wherein the upper end of the cryogen supply pipe is located at or near an upper extremity of the cryogen vessel.

32. The cryogen cooling system according to claim 31 wherein an umbrella is provided above the upper end of the cryogen supply pipe.

33. A cryogen cooling system for cooling a superconducting magnet, comprising:
a cryogen vessel linked to a cooling loop arrangement in thermal contact with the superconducting magnet;
a recondensing chamber arranged such that a lower extremity of the cryogen vessel is above a lower extremity of the recondensing chamber;
a recondensing refrigerator arranged to recondense cryogen gas within the recondensing chamber; and
a heater positioned to heat gaseous cryogen within the recondensing chamber, and wherein the recondensing chamber is hydraulically connected to the cryogen vessel by a first pipe which links an upper part of the recondensing chamber with an upper part of the cryogen vessel to provide a passage for flow of cryogen gas from the cryogen vessel to the recondensing chamber through a one-way valve, and a second pipe which links lower parts of the recondensing chamber and the cryogen vessel to provide a passage for flow of liquid cryogen in the recondensing chamber from the recondensing chamber to the cryogen vessel.

34. The cryogen cooling system according to claim 33 further comprising a sensor for detecting a minimum level of the liquid cryogen in the recondensing chamber.

35. The cryogen cooling system according to claim 33 further comprising a sensor for detecting a maximum level of the liquid cryogen in the recondensing chamber.

36. The cryogen cooling system according to claim 33 further comprising a sensor for detecting a maximum level of the liquid cryogen in the cryogen vessel.

37. The cryogen cooling system according to claim 34 further comprising a controller arranged to energize and de-energize the heater in response to signals provided by the sensor, or one of the sensors.

38. The cryogen cooling system according to claim 33 wherein the heater is integrated into the recondensing refrigerator.

39. The cryogen cooling system according to claim 33 wherein the heater is attached to an outer surface of the recondensing chamber in thermal contact with the recondensing chamber.

40. A method for replenishing a cryogen vessel of a cryogen cooling system for cooling a superconducting magnet with liquid cryogen, said cryogen cooling system comprising a cryogen vessel linked to a cooling loop arrangement in thermal contact with the superconducting magnet, a recondensing chamber arranged such that a lower extremity of the cryogen vessel is above a lower extremity of the recondensing chamber, a recondensing refrigerator arranged to recondense cryogen gas within the recondensing chamber, and a heater positioned to heat gaseous cryogen within the recondensing chamber, and wherein the recondensing chamber is hydraulically connected to the cryogen vessel by a cryogen supply pipe, an upper end of the cryogen supply pipe being exposed to cryogen gas in the cryogen vessel and a lower end of cryogen supply pipe being exposed to an interior of the recondensing chamber towards or at its lower extremity, comprising the steps of:
a) providing the cryogen in a closed volume comprising the recondensing chamber, the cryogen supply pipe, the cryogen vessel and the cooling loop arrangement;
b) operating the recondensing refrigerator to liquefy the cryogen gas within the recondensing chamber, thereby reducing a gas pressure within the recondensing chamber to below a gas pressure within the cryogen vessel;
c) supplying the cryogen gas from the cryogen vessel through the cryogen supply pipe to the recondensing chamber;
d) continuing to liquefy the cryogen gas within the recondensing chamber to provide a volume of the liquid cryogen within the recondensing chamber;
e) energizing the heater to heat the cryogen gas within the cryogen vessel to thereby increase a gas pressure within the recondensing chamber above a gas pressure within the cryogen vessel;
f) driving at least part of the volume of the liquid cryogen from the recondensing chamber through the cryogen supply pipe to the cryogen vessel by a difference in gas pressures in the recondensing chamber and the cryogen vessel; and
g) de-energizing the heater.

41. The method according to claim 40 further comprising cyclically repeating steps (b)-(g).

42. The method according to claim 41 wherein step (e) commences at predetermined time intervals corresponding to an expected accumulation of quantities of the liquid cryogen within the recondensing chamber.

43. The method according to claim 40 wherein step (e) commences in response to an output of a sensor indicating that a maximum level of the liquid cryogen is present in the recondensing chamber.

44. The method according to claim 40 wherein step (g) commences in response to an output of a sensor indicating that a minimum level of the liquid cryogen is present in the recondensing chamber.

45. The method according to claim 40 wherein step (e) commences in response to an output of a sensor indicating that a minimum level of the liquid cryogen is present in the cryogen vessel.

46. The method according to claim 40 wherein step (g) commences in response to an output of a sensor indicating that a maximum level of the liquid cryogen is present in the cryogen vessel.

47. The method according to claim 40 wherein steps (e) and (f) continue for fixed periods of time.

48. The method according to claim 40 wherein operation of the recondensing refrigerator is suspended during steps (e) and (f).
